(19) United States
(12) Patent Application Publication
(10) Pub. No.: US 2007/0200133 A1
(43) Pub. Date: Aug. 30, 2007

(54) LED ASSEMBLY AND MANUFACTURING METHOD

(76) Inventors: Akira Hashimoto, Kyoto (JP); Masaaki Katsumata, Osaka (JP); Masaaki Hayama, Nara (JP); Kenichi Endou, Fukushima (JP); Kenji Endou, Fukushima (JP); Hitoshi Hirano, Fukushima (JP); Hidenori Katsumura, Hyogo (JP); Tatsuya Inoue, Osaka (JP)

Correspondence Address: MCDERMOTT WILL & EMERY LLP, 600 13TH STREET, NW, WASHINGTON, DC, 20005-3096, US

(21) Appl. No.: 11/579,770

(22) PCT Filed: Mar. 31, 2006
(86) PCT No.: PCT/JP06/06798

§ 371 Date: Nov. 7, 2006

(30) Foreign Application Priority Data
Apr. 1, 2005 (JP) 2005-105873
Jun. 6, 2005 (JP) 2005-165112

(51) Int. Cl. H01L 33/00

(52) U.S. Cl. 257/100; 439/701

(57) ABSTRACT

An LED assembly including a wiring substrate with an opening at its center; a heat sink housed inside the opening; an LED chip mounted on the heat sink; a connecting section for electrically coupling the LED chip and wiring substrate; and a transparent resin covering the LED chip and connecting section. Heat generated from the LED chip is efficiently dissipated, and high productivity is also achievable.

### RELATED APPLICATIONS

This application is the U.S. National Phase under 35 U.S.C. § 371 of International Application No. PCT/JP2006/0306798, filed on Mar. 31, 2006, which in turn claims the benefit of Japanese Application No.2005-105873, filed on Apr. 1, 2005, and Japanese Application No.2005-165112, filed on Jun. 6, 2005 the disclosures of which Applications are incorporated by reference herein.

### TECHNICAL FIELD

The present invention relates to surface-mount LED assemblies with good heat dissipation performance and their manufacturing methods.

### BACKGROUND ART

In a conventional structure of light emitting diode (LED) assemblies, an LED chip is mounted on a range of substrates and coupled to preformed electrode patterns on the range of substrates by wire-bonding or bump-mounting. A transparent insulator that also acts as a lens is then formed on the surface of the LED chip. (For example, this structure is disclosed in Japanese Patent Unexamined Publication No. 2004-207369.)

FIG. 40 is a sectional view of a conventional surface-mount LED assembly. As shown in FIG. 40, the conventional surface-mount LED assembly includes wiring substrate 100 on which conductor wiring sections 200 and 300 are formed at both ends; LED chip 500 placed on one conductor wiring section 200 using adhesive 400; wire 600, made typically of gold, for coupling LED chip 500 and conductor wiring sections 200 and 300 by wire-bonding; and protective layer 700 formed so as to cover the surfaces of this wire 600 and LED chip 500.

Wiring substrate 100 is a flat copper-clad printed circuit board. LED chip 500 is die-bonded on wiring substrate 100 using Ag paste as adhesive 400. Conductor wiring sections 200 and 300 on both ends of wiring substrate 100 become soldering sections when the LED assembly is mounted, typically on a printed circuit board.

However, the above structure shows low heat dissipation performance if the LED assembly emits light continuously for long periods or when a high current is supplied to the LED chip for lighting purposes. In addition, with respect to reliability, electrostatic breakdown is becoming problematic as advances in semiconductor components allow them to be driven at ever-lower voltages.

### SUMMARY OF THE INVENTION

An LED assembly of the present invention includes a wiring substrate in which an opening is created at its center, a heat sink fitted into the opening, an LED chip mounted on the heat sink, a connecting section for electrically coupling the LED chip and the wiring substrate, and a transparent resin covering the LED chip and the connecting section.

With the above structure, the LED assembly of the present invention efficiently dissipates the heat generated from the LED chip.

Furthermore, the LED assembly of the present invention has the opening at the center of the wiring substrate with a built-in varistor element. The heat sink onto which the LED chip is placed is bonded inside this opening. The LED chip and the varistor element built into the wiring substrate are then coupled in parallel, and a transparent resin covers the LED chip.

With the above structure, the LED assembly of the present invention allows efficient dissipation of the heat generated from the LED chip. Accordingly, the present invention offers a surface-mount LED assembly with good antistatic characteristic and its manufacturing method.

### BRIEF DESCRIPTION OF DRAWINGS

FIG. 1 is a sectional view of an LED assembly in accordance with a first exemplary embodiment of the present invention.

FIG. 2 is a sectional view of another example of the LED assembly in accordance with the first exemplary embodiment of the present invention.

FIG. 3 is a sectional view illustrating a manufacturing method of the LED assembly in accordance with the first exemplary embodiment of the present invention.

FIG. 4 is a sectional view illustrating the manufacturing method of the LED assembly in accordance with the first exemplary embodiment of the present invention.

FIG. 5 is a sectional view illustrating the manufacturing method of the LED assembly in accordance with the first exemplary embodiment of the present invention.

FIG. 6 is a sectional view illustrating the manufacturing method of the LED assembly in accordance with the first exemplary embodiment of the present invention.

FIG. 7 is a sectional view illustrating the manufacturing method of the LED assembly in accordance with the first exemplary embodiment of the present invention.

FIG. 8 is a sectional view of an LED assembly in accordance with a second exemplary embodiment of the present invention.

FIG. 9 is a sectional view of another example of the LED assembly in accordance with the second exemplary embodiment of the present invention.

FIG. 10 is a sectional view illustrating a manufacturing method of the LED assembly in accordance with a third exemplary embodiment of the present invention.

FIG. 11 is a sectional view illustrating the manufacturing method of the LED assembly in accordance with the third exemplary embodiment of the present invention.

FIG. 12 is a sectional view illustrating the manufacturing method of the LED assembly in accordance with the third exemplary embodiment of the present invention.

FIG. 13 is a sectional view illustrating the manufacturing method of the LED assembly in accordance with the third exemplary embodiment of the present invention.

FIG. 14 is a sectional view of another example of the LED assembly in accordance with the third exemplary embodiment of the present invention.

FIG. 15 is a sectional view of an LED assembly in accordance with a fourth exemplary embodiment of the present invention.

FIG. 16 is a sectional view of another example of the LED assembly in accordance with the fourth exemplary embodiment of the present invention.

FIG. 17 is a sectional view illustrating a manufacturing method of the LED assembly in accordance with the fourth exemplary embodiment of the present invention.

FIG. 18 is a sectional view illustrating the manufacturing method of the LED assembly in accordance with the fourth exemplary embodiment of the present invention.

FIG. 19 is a sectional view illustrating the manufacturing method of the LED assembly in accordance with the fourth exemplary embodiment of the present invention.

FIG. 20 is a sectional view illustrating the manufacturing method of the LED assembly in accordance with the fourth exemplary embodiment of the present invention.

FIG. 21 is a sectional view illustrating the manufacturing method of the LED assembly in accordance with the fourth exemplary embodiment of the present invention.

FIG. 22 is a sectional view illustrating the manufacturing method of the LED assembly in accordance with the fourth exemplary embodiment of the present invention.

FIG. 23 is a sectional view of an LED assembly in the fifth exemplary embodiment of the present invention.

FIG. 24 is a sectional view of another example of the LED assembly in accordance with the fifth exemplary embodiment of the present invention.

FIG. 25 is a sectional view of an LED assembly in accordance with a sixth exemplary embodiment of the present invention.

FIG. 26 is a sectional view of another example of the LED assembly in accordance with the sixth exemplary embodiment of the present invention.

FIG. 27 is a sectional view illustrating a manufacturing method of the LED assembly in accordance with the sixth exemplary embodiment of the present invention.

FIG. 28 is a sectional view illustrating the manufacturing method of the LED assembly in accordance with the sixth exemplary embodiment of the present invention.

FIG. 29 is a sectional view illustrating the manufacturing method of the LED assembly in accordance with the sixth exemplary embodiment of the present invention.

FIG. 30 is a sectional view illustrating the manufacturing method of the LED assembly in accordance with the sixth exemplary embodiment of the present invention.

FIG. 31 is a sectional view illustrating the manufacturing method of the LED assembly in accordance with the sixth exemplary embodiment of the present invention.

FIG. 32 is a sectional view illustrating the manufacturing method of the LED assembly in accordance with the sixth exemplary embodiment of the present invention.

FIG. 33 is a sectional view of an LED assembly in accordance with a seventh exemplary embodiment of the present invention.

FIG. 34 is a sectional view illustrating a manufacturing method of the LED assembly in accordance with the seventh exemplary embodiment of the present invention.

FIG. 35 is a sectional view illustrating the manufacturing method of the LED assembly in accordance with the seventh exemplary embodiment of the present invention.

FIG. 36 is a sectional view illustrating the manufacturing method of the LED assembly in accordance with the seventh exemplary embodiment of the present invention.

FIG. 37 is a sectional view illustrating the manufacturing method of the LED assembly in accordance with the seventh exemplary embodiment of the present invention.

FIG. 38 is a sectional view illustrating the manufacturing method of the LED assembly in accordance with the seventh exemplary embodiment of the present invention.

FIG. 39 is a sectional view of another example of the LED assembly in accordance with the seventh exemplary embodiment of the present invention.

FIG. 40 is a sectional view of a conventional LED assembly.

### REFERENCE MARKS IN THE DRAWINGS

| | |
|---|---|
| 1 | Wiring substrate |
| 2 | Wiring pattern |
| 3 | Adhesive |
| 4 | LED chip |
| 5 | Wire |
| 6 | Transparent resin |
| 7 | Heat sink |
| 7a, 7b, 7c, 7d | Heat sink |
| 8 | Reflective coating |
| 9 | Reflecting surface |
| 10 | Claw |
| 11 | Through-hole |
| 12 | Opening |
| 13 | Wiring pattern |
| 14 | Wiring pattern |
| 15 | Cavity |
| 34 | Heat sink |
| 101 | Wiring substrate |
| 102 | Wiring pattern |
| 103 | Wiring pattern |
| 104 | Adhesive |
| 105 | LED chip |
| 105a | Flip-chip type LED chip |
| 106 | Wire |
| 107 | Transparent resin |
| 108, 108a, 108b, 108c | Heat sink |
| 108d, 108e, 108f | Heat sink |
| 109 | Reflecting surface |
| 110 | Reflective coating |
| 111 | Claw |
| 112 | Through-hole |
| 122 | Resin paste |
| 123 | Insulation paste |
| 131 | Varistor material |
| 132 | Varistor electrode |
| 133 | Varistor electrode |
| 134 | Varistor electrode |
| 135 | Varistor element |
| 136 | Bump |

### DESCRIPTION OF PREFERRED EMBODIMENTS

### First Exemplary Embodiment

An LED assembly and its manufacturing method in the first exemplary embodiment of the present invention are described below with reference to drawings.

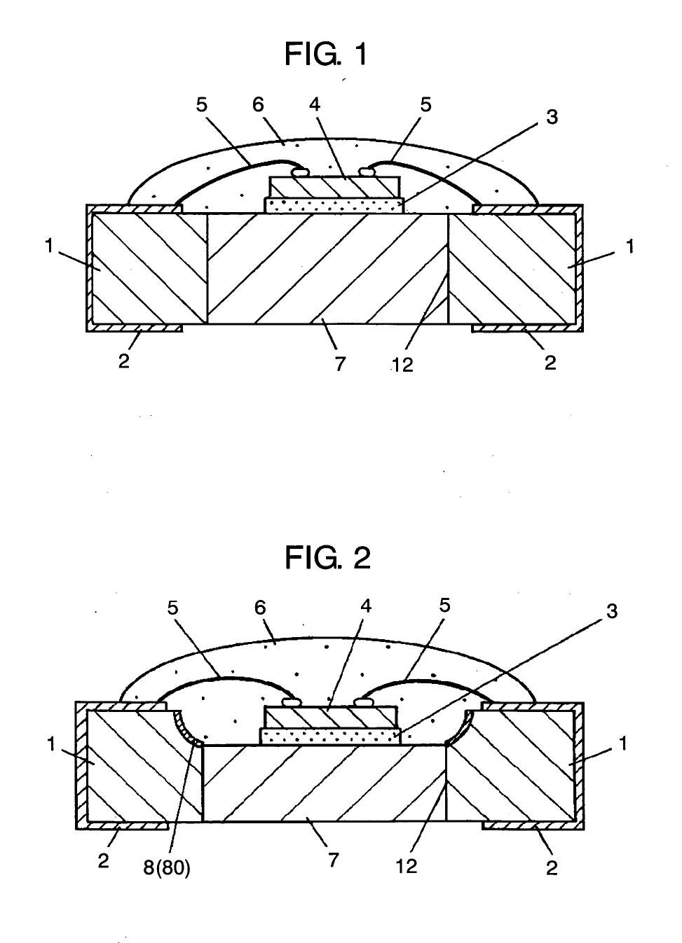

FIG. 1 is a sectional view illustrating the structure of a surface-mount LED assembly in the first exemplary embodiment of the present invention. FIG. 2 is a sectional view of another example of the LED assembly.

In FIG. 1, wiring substrate 1 is preferably a resin substrate, typically made of glass-epoxy resin, or a ceramic substrate, typically an alumina substrate. Wiring pattern 2, which acts as both wiring and a terminal electrode of a surface-mount assembly, is formed on this wiring substrate 1. This wiring pattern 2 is preferably made of an electrode material, typically copper or silver.

Opening 12 is created at the center of this wiring substrate 1. Heat sink 7, which has better heat conductivity than wiring substrate 1, is disposed inside this opening 12. LED chip 4 is die-bonded onto one face of this heat sink 7 using conductive adhesive 3. A terminal pad provided on a part of wiring pattern 2 and LED chip 4 are electrically coupled by wire-bonding using wire 5, typically made of gold.

In the above structure, it is important to set the heat conductivity of heat sink 7 higher than the heat conductivity of wiring substrate 1. With respect to productivity, wiring substrate 1 is preferably made of a resin substrate, typically glass epoxy. Wiring substrate 1 can also be a polyimide substrate, glass substrate, SOI substrate or enameled substrate, or similar. The SOI substrate is a silicon substrate whose surface is insulated by an oxide film. For LED assemblies that require higher luminance and higher reliability in heat-resistance, a ceramic substrate mainly containing alumina is preferably used.

Heat sink 7 is preferably made of metal with good heat conductivity. In particular, metals with good heat conductivity which are preferably used include aluminum which has heat conductivity of 240 W/m·K, copper which has heat conductivity of 400 W/m·K, silver which has heat conductivity of 430 W/m·K, or gold, which has heat conductivity of 340 W/m·K. In the present invention, these metal plates with good heat conductivity are used for heat sink 7, and a glass epoxy substrate of high productivity, a resin substrate typically polyamide or polyimide, or a ceramic substrate with good heat resistance are used for wiring substrate 1.

The LED assembly with even higher heat resistance and insulation performance is achievable by the use of ceramic substrates which has good heat resistance and insulation performance, typically alumina, forsterite, steatite, or low-temperature co-firing ceramic substrates. For purposes which require even better heat dissipation performance and heat resistance, a ceramic material which has even better heat conductivity, typically aluminum or silicon carbide, may be used.

In the structure shown in FIG. 1, a copper plate that enables heat dissipation is placed on a circuit board on which the LED assembly will be mounted, and heat sink 7 is fixed to this copper plate using adhesive with good heat conductivity. This can dissipate directly the heat discharged from heat sink 7 to the copper plate disposed on the circuit board.

When the LED assembly is mounted, typically on a circuit board, the use of a metal for heat sink 7 establishes grounding to the circuit board via heat sink 7 or increases the mounting strength by fixing heat sink 7 onto the circuit board using adhesive with good heat conductivity or solder.

In addition, when insulation is needed between LED chip 4 and heat sink 7, a thin insulation coating can be formed on one face of heat sink 7 made of metal where LED chip 4 will be mounted. However, since the insulation coating hinders heat dissipation, the insulation coating is preferably made as thin as possible.

In addition, heat sink 7 can be made of a ceramic material with high heat conductivity, typically aluminum nitride or silicon carbide at the minimum amount necessary to increase the heat dissipation of LED chip 4.

Next, wiring pattern 2 is formed by photo-etching or plating a copper foil attached to the glass-epoxy substrate or a copper electrode formed on the surface of the alumina substrate, or by printing conductive paste. As for this conductive paste, resin conductive paste containing silver or copper can be used. Alternatively, high-conductivity paste containing nano-metal powder or organic metal can also be used.

When ceramic materials, typically alumina substrate, are used for wiring substrate 1, high-temperature firing conductive paste, which is fired between 500° C. and 1400° C., can be used. This high-temperature firing paste is preferably a noble metal, typically silver, gold, platinum, palladium (Pd) or their alloys; or a base metal, typically copper, nickel, tungsten, molybdenum, or their alloys.

For soldering the LED assembly onto the circuit board, a plated nickel film or a plated tin film is preferably laminated on a soldering portion of wiring pattern 2 to avoid any changes in the material of wiring pattern 2 by inter-diffusion of the electrode materials.

Transparent resin 6, which insulates and protects LED chip 4 and wire 5 and also acts as a lens, is preferably made typically of thermosetting acrylic resin or epoxy resin. Transparent resin 6 covers the entire LED chip 4, and also covers wire 5 and a bonding pad which configure a connecting section between LED chip 4 and wiring substrate 1.

Next, another structure of the LED assembly shown in FIG. 2 is described.

A significant difference in the structure of the LED assembly shown in FIG. 2 compared to that of the LED assembly in FIG. 1 is a cavity formed by providing heat sink 7, which is thinner than that of the wiring substrate 1 to lower the level of the placement area of LED chip 4, to below the surface level of wiring substrate. This cavity is configured with one face of heat sink 7 as the bottom and the inner side face of opening 12 in wiring substrate 1. In addition, taper 80 is provided on the inner periphery of opening 12 configuring this cavity. A slope of this taper 80 is used as a reflector when LED chip 4 emits light.

This structure realizes an LED assembly with better luminous efficiency compared to that of the LED assembly shown in FIG. 1. The taper on the inner periphery of this opening 12 is preferably processed to a shape that efficiently reflects light. More specifically, a conical or curved taper 80 achieves an LED assembly with good reflectivity.

Still more, reflective coating 8, which is a thin film made of a metal with good reflectivity, is provided on the surface of the inner periphery of opening 12 where this taper 80 is provided. Provision of this reflective coating 8 achieves an LED assembly with even better luminous efficiency. This reflective coating 8 can be applied by forming a thin metal film.

The reflective coating 8 may also be formed on the surface of heat sink 7 on which LED chip 4 is mounted. This achieves an LED assembly with even better reflectivity.

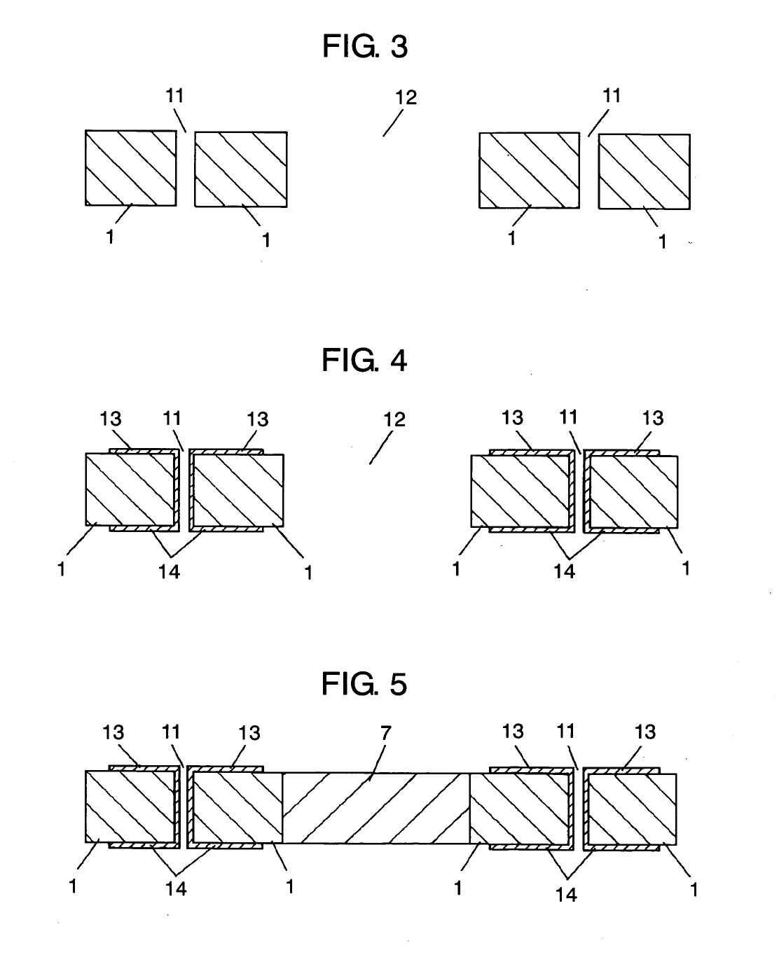

Next, a method of manufacturing the LED assembly of the present invention is described with reference to FIGS. 3 to 7. In the first exemplary embodiment, the method of manufacturing the LED assembly configured with heat sink 7 made of metal and wiring substrate 1 made of the alumina substrate is described.

In the first step, as shown in FIG. 3, through hole 11 which is a splitting groove for dividing into individual LED assemblies and which also becomes a terminal electrode of the split LED assembly, and opening 12 for inserting heat sink 7 are created in the alumina substrate in advance to fabricate wiring substrate 1 (hereafter referred to as alumina substrate 1).

Then, as shown in FIG. 4, wiring patterns 13 and 14 are screen-printed, using silver paste, on both faces of alumina substrate 1 and the inner wall of through hole 11.

In the second step, as shown in FIG. 5, metal which has good heat conductivity, typically aluminum or copper, is processed into heat sink 7 with a predetermined shape. Then, in the third step, this heat sink 7 is press-fitted or bonded using adhesive inside opening 12. As for adhesive, conductive adhesive with good heat dissipation performance such as for thermal via and die-bonding is preferably used to suppress the drop in heat conductivity due to the adhesive.

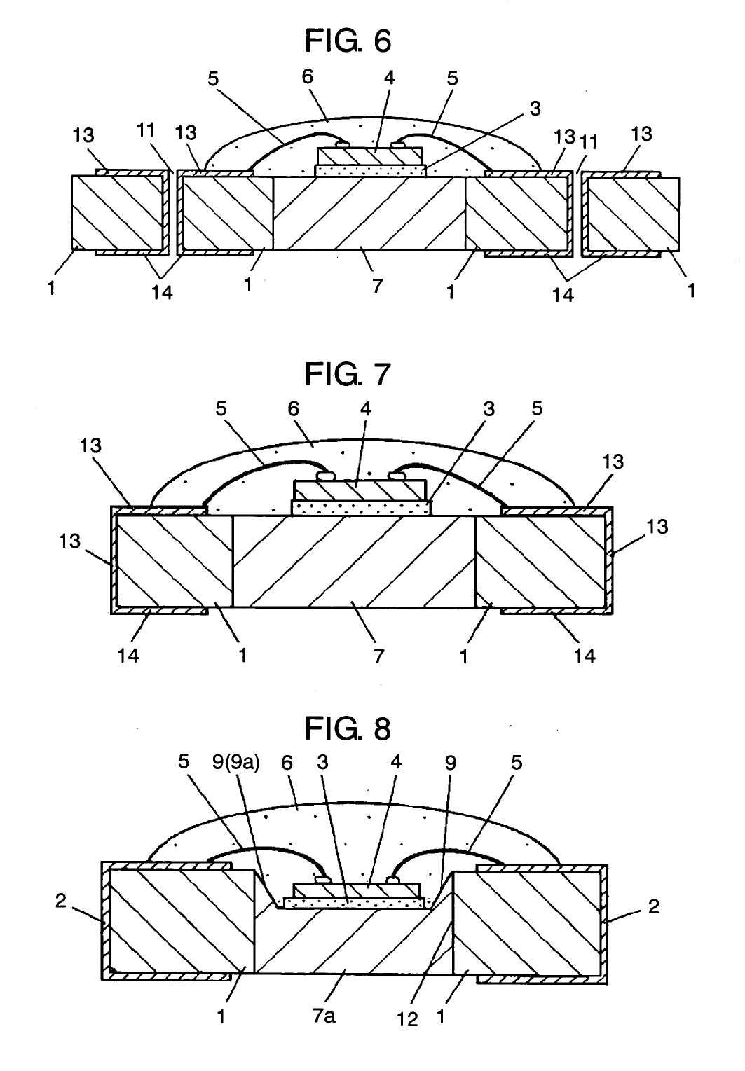

In the fourth step, as shown in FIG. 6, LED chip 4 is fixed onto one face of heat sink 7 using adhesive 3.

Then, in the fifth step, LED chip 4 and an electrode pad provided on wiring pattern 13 of wiring substrate 1 are electrically coupled with gold wire 5 by wire-bonding using a wire bonder.

In the sixth step, transparent resin 6, which has good transparency, typically acrylic resin or epoxy resin, is applied. Transparent resin 6 insulates and protects LED chip 4 and also acts as a lens for converging the light emitted from LED chip 4. Here, an appropriate viscosity or application method is selected to form transparent resin 6 with a predetermined lens shape. This transparent resin 6 may also act to reinforce bonding between wiring substrate 1 and heat sink 7.

Next, as shown in FIG. 7, alumina substrate 1 is cut or divided into half at the through hole 11 to complete an individual surface-mount LED assembly.

As described above, in the first exemplary embodiment, heat sink 7 with good heat conductivity is provided inside opening 12 created in a part of wiring substrate 1 where LED chip 4 will be placed. This achieves a surface-mount LED assembly with both good heat dissipation performance and high productivity, and its manufacturing method.

### Second Exemplary Embodiment

An LED assembly and its manufacturing method in the second exemplary embodiment of the present invention are described below with reference to drawings.

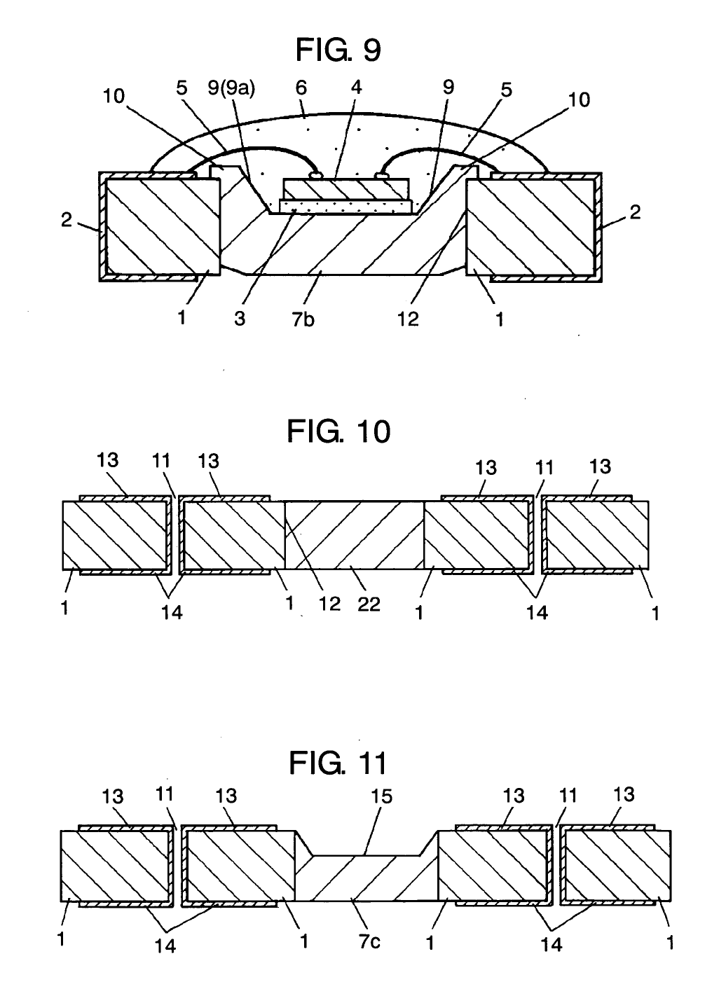

FIG. 8 is a sectional view illustrating the structure of a surface-mount LED assembly in the second exemplary embodiment of the present invention. FIG. 9 is a sectional view of another example.

In FIGS. 8 and 9, a significant difference in the structure of the LED assembly in the second exemplary embodiment, compared to that of the first exemplary embodiment, is the shape of heat sinks 7a and 7b. Heat sinks 7a and 7b in the second exemplary embodiment are characterized by their cavity created by making a concave portion.

Heat sinks 7a and 7b shown in FIGS. 8 and 9 have a cavity formed by machining metal with good heat conductivity, typically aluminum, copper, or silver. A space for mounting LED chip 4 is provided on the bottom of this cavity.

The inner periphery of the concave portion which forms the cavity in these heat sinks 7a and 7b is tapered by molding or polishing to form reflecting surface 9. This reflecting surface 9 is tapered at a predetermined angle for efficiently converging the light emitted from LED chip 4 placed on the bottom of the cavity in heat sinks 7a and 7b, and increasing the luminous efficiency. Accordingly, light emission from the LED assembly is controllable.

This taped reflecting surface 9 on the inner periphery of the concave portion can be processed to a mirrored surface to further improve light reflection.

In addition, this reflective coating 9a of a material with a higher reflectivity may be applied to this reflecting surface 9, using thin-film technologies including plating, deposition or the like on the surface, so as to more efficiently reflect the light from LED chip 4. This can achieve an LED assembly with even higher reflectivity. Accordingly, an LED assembly of high productivity and luminous efficiency is also achievable by using metal with good heat conductivity for heat sinks 7a and 7b, and forming a reflective coating with good reflectivity on the inner periphery of the concave portion created in heat sinks 7a and 7b.

In addition, claw 10 may be simultaneously formed by molding, using a metal plate for heat sink 7b, as shown in FIG. 9. Provision of claw 10 regulates and retains the depth of insertion to a certain level when heat sink 7 is inserted into opening 12 in wiring substrate 1.

This claw 10 may have continuous protrusions like a guard.

As described above, in the second exemplary embodiment, a cavity is easily created on heat sink 7 by machining heat sinks 7a and 7b made of metal on which LED chip 4 will be placed. In addition, reflecting surface 9 may be simultaneously formed. Accordingly, this structure can achieve a shorter LED assembly of high productivity.

A ceramic material that has good heat conductivity can also be molded into the shape of heat sinks 7a and 7b. In this case, an LED assembly with good heat resistance is achievable in addition to the above effects

### Third Exemplary Embodiment

An LED assembly and its manufacturing method in the third exemplary embodiment of the present invention are described below with reference to drawings.

FIGS. 10 to 13 are sectional views illustrating the manufacturing method of LED assembly in the third exemplary embodiment of the present invention. FIG. 14 is a sectional view of another example of the LED assembly.

A surface-mount LED assembly in the third exemplary embodiment of the present invention basically has a structure shown in FIG. 8. A significant difference in the LED assembly in the third exemplary embodiment, compared to that of the second exemplary embodiment, is the material of heat sink 7a. The LED assembly in the third exemplary embodiment uses heat sink 7c instead of heat sink 7a in FIG. 8. This heat sink 7c is made of resin containing metal filler (heat-conducting filler) which has good heat conductivity. This metal filler used for heat sink 7c is described next. First, resin paste is made by kneading powder, typically copper, aluminum, gold, or silver, with epoxy resin. The resin paste made is filled inside opening 12 created on wiring substrate 1, and then thermally cured. Thermal curing allows formation of heat sink 7c and bonding with wiring substrate 1 simultaneously. Accordingly, the LED assembly of high productivity is achievable.

Still more, if inorganic filler is used instead of this metal filler, the LED assembly with good insulation performance is achievable in addition to the effect described above. The use of inorganic filler, typically aluminum oxide, aluminum nitride, silicon carbide, or magnesium oxide, can achieve the LED assembly with good heat dissipation performance and high productivity.

In other words, the resin paste, to which a heat-conducting filler of metal or ceramic powder with good heat conductivity is added, is filled in opening 12 at wiring substrate 1, and then this resin paste is thermally cured for fabricating heat sink 7c. In the same step, a concave portion of heat sink 7c is also created by molding using dies or by machining to configure a cavity.

Other points of the structure are mostly the same as the second exemplary embodiment, and thus their descriptions are omitted here.

This structure allows attachment of wiring substrate 1 and heat sink 7c at the same time as thermally curing the resin paste. In addition, expansion coefficients of wiring substrate 1 and heat sink 7c are controllable by changing the material composition of resin paste.

Next, the method of manufacturing the LED assembly in the third exemplary embodiment is described with reference to FIGS. 10 to 14.

In the first step, as shown in FIG. 10, wiring patterns 13 and 14 are formed and through hole 11 and opening 12 are created to fabricate an alumina substrate into wiring substrate 1.

In the second step, resin paste 22 containing metal filler, typically silver, is filled by screen-printing. Then, in the third step, filled resin paste 22 is thermally cured to fabricate heat sink 7. At the same time, heat sink 7 is attached to wiring substrate 1. Metal filler used in the resin paste is preferably metal powder with good heat conductivity, typically gold, silver, aluminum, or copper. Heat sink 7 with an intended heat conductivity can be designed by changing the content rate of this metal filler.

Other than the metal filler, inorganic filler is also applicable. The use of ceramic powder with good heat conductivity, typically aluminum oxide, aluminium nitride, silicon carbide, or magnesium oxide, achieves the LED assembly with good durability including heat resistance and moisture resistance.

For this resin paste 22, a material with less shrinkage by curing is preferably used.

Next, thermally-cured resin paste 22 is machined into the shape of heat sink 7c shown in FIG. 11. Heat sink 7c with this shape achieves the function same as heat sink 7a described in the second exemplary embodiment. Then, wiring patterns 13 and 14 are printed using conductive paste, typically silver or copper, on both faces of wiring substrate 1 and an inner wall of through hole 11.

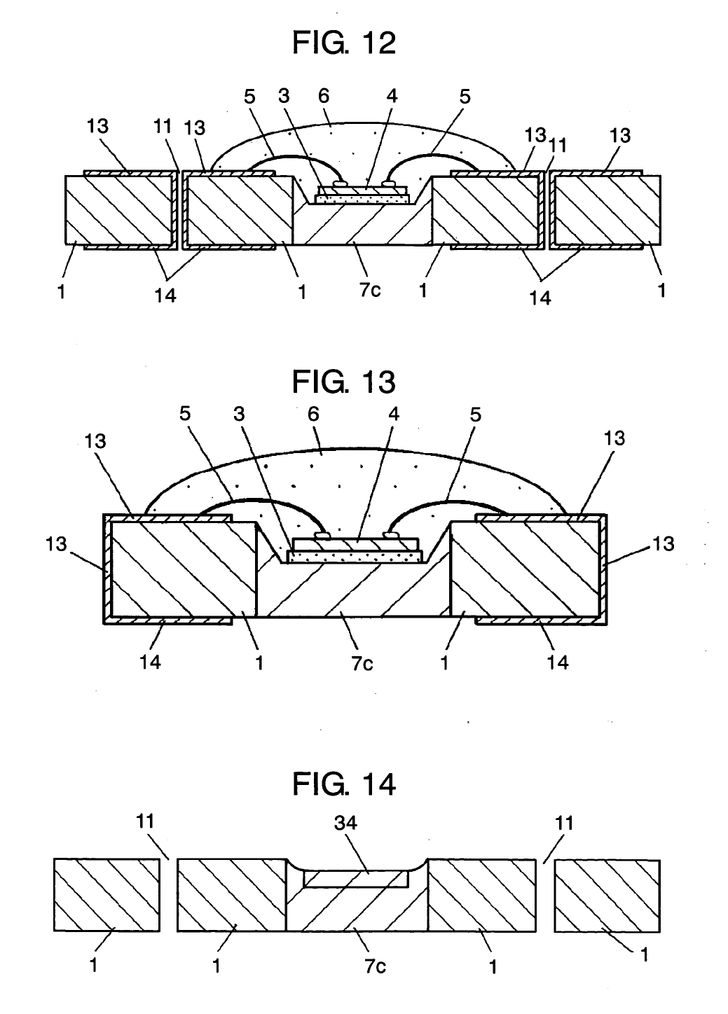

In the fourth step, LED chip 4 is fixed onto the bottom of the concave portion of heat sink 7, as shown in FIG. 12, using adhesive 3.

Next, in the fifth step, LED chip 4 and a pad provided on a part of wiring pattern 13 are electrically coupled with gold wire 5 by wire-bonding using a wire bonder.

In the sixth step, LED chip 4 and wire 5 are covered with transparent resin 6, which has good transparency. This transparent resin 6 protects LED chip 4 and wire 5, and also acts as a lens for converging the emitted light. Then, wiring substrate 1 is divided at through hole 11 to complete an individual surface-mount LED assembly with the predetermined shape as shown in FIG. 13.

As described above, in the third exemplary embodiment, heat sink 7c of high productivity is formed on wiring substrate 1 on which LED chip 4 will be placed. This structure thus offers a smaller and shorter LED assembly, and its manufacturing method.

Still more, as shown in FIG. 14, heat sink 34 made of metal or ceramic material with better flatness and heat conductivity may be placed on the bottom of the concave portion of heat sink 7c made of the resin paste containing filler. This structure achieves an even smaller LED assembly and its manufacturing method.

Metal materials with good heat conductivity, typically gold, silver, aluminum, or copper; or ceramic materials, typically alumina, aluminium nitride, silicon carbide, or magnesium oxide; may be used for the above heat sink 34.

### Fourth Exemplary Embodiment

An LED assembly and its manufacturing method in the fourth exemplary embodiment of the present invention are described below with reference to drawings.

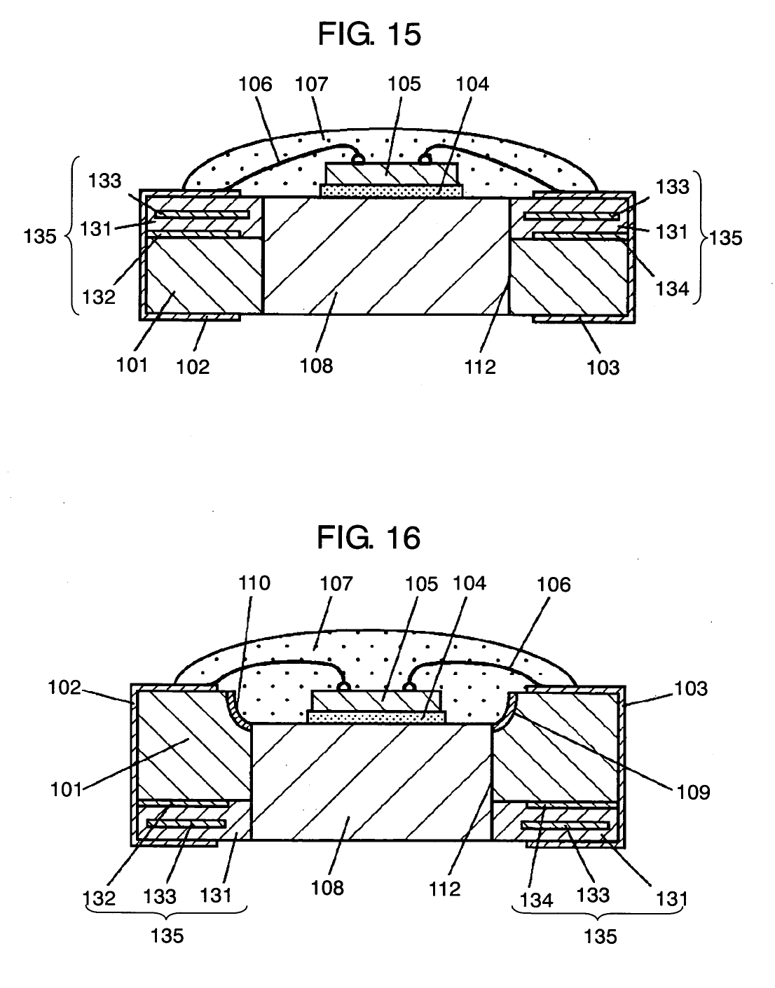

FIG. 15 is a sectional view illustrating the structure of a surface-mount LED assembly in the fourth exemplary embodiment of the present invention. FIG. 16 is a sectional view of another example of the LED assembly.

In FIG. 15, wiring substrate 101 is preferably a ceramic substrate with a heat resistance of 500° C. or higher, typically alumina, forsterite, or steatite, since varistor element 135 made of ceramic is built into wiring substrate 101. Varistor electrode 132 faces varistor electrode 133 via varistor material 131, and varistor electrode 134 faces varistor electrode 133 via varistor material 131 to form varistor element 135 on one face of this wiring substrate 101.

For example, wiring substrate 101 with built-in varistor element 135 can be formed by alternately laminating a green sheet made of varistor material 131 and a printed wiring layer, which is printed electrode paste, on a fired alumina substrate; and then firing all together. Alternatively, varistor element 135 can be formed typically on an alumina substrate by making each paste made of its respective material, and then screen-printing them on the alumina substrate.

Another possible method is to laminate a green sheet of a glass ceramic material for low temperature co-fired ceramic (LTCC) substrates and a green sheet of varistor element 135; and then fire simultaneously to form wiring substrate 101 with built-in varistor element 135. In this case, varistor element 135 can be formed in the inner layers of wiring substrate 101 in addition to the surface and rear faces of wiring substrate 101. Accordingly, for example, a chip component can be mounted on the surface of wiring substrate 101, offering wiring substrate 101 with a higher level of flexibility in design.

Varistor material 131 used for this varistor element 135 is preferably ZnO varistor material. This ZnO varistor contains ZnO as a main constituent, and its content rate is 80 wt % or higher. As an accessory constituent, Bi₂O₃, BaO, SrO, Pr₂O₃, and similar are preferable. When the content rate of ZnO is 80 wt % or higher, the electrical insulating characteristic improves. Still more, it is preferable to add typically CoO, MnO, or Al₂O₃ to improve the non-ohmic characteristics. Furthermore, it is preferable to add typically Sb₂O₃, Cr₂O₃, glass frit, or B₂O₃ to stabilize the crystal grain boundary against electrical loads and environmental conditions and to improve reliability.

Wiring patterns 102 and 103 which act as wiring and terminal electrodes of a surface-mount assembly are formed on wiring substrate 101. These wiring patterns 102 and 103 are preferably made of an electrode material with good conductivity, typically copper, nickel, silver, or their alloys. Wiring patterns 102 and 103 are formed by photo-etching or plating a copper electrode formed on wiring substrate 101, or by applying conductive paste. An electrode material with good conductivity may be used for this conductive paste. Alternatively, conductive paste with good conductivity containing nano-metal powder or organic metal is also applicable. For this conductive paste, noble metals, typically silver, gold, platinum, or their alloys, or base metals typically copper, nickel, tungsten, molybdenum, or their alloys can be used. The same electrode is applicable to varistor electrodes 132, 133, and 134. However, it is preferable to select an electrode material which does not degrade the characteristic of the varistor due to diffusion of the electrode material into varistor element 135. In particular, a copper electrode may diffuse, depending on the material composition of varistor material 131. It is preferable to select an appropriate electrode material that does not degrade the characteristic of the varistor material.

Next, a wiring configuration of the electrodes of varistor element 135 and wiring patterns 102 and 103 in FIG. 15 is described. In FIG. 15, varistor electrode 132 is coupled to wiring pattern 102. This varistor electrode 132 builds varistor element 135 having a capacitor function by disposing this varistor electrode 132 in a way such that to face varistor electrode 133 via varistor material 131. Varistor electrode 133 also builds varistor element 135 having a capacitor function by disposing this varistor electrode 133 in a way such that to face varistor electrode 134 via varistor material 131. Accordingly, varistor element 135 in FIG. 15 has a structure in which two varistors are disposed in series. This structure thus can achieve a smaller LED assembly with built-in varistor.

Since varistor element 135 can demonstrate its function by building at least one element in wiring substrate 101, varistor element 135 is formed at least on a part of one face of wiring substrate 101 to demonstrate its effects.

Next, opening 112 is created at the center of this wiring substrate 101, and heat sink 108 with heat conductivity better than wiring substrate 101 is disposed inside this opening 112.

LED chip 105 is disposed on one face of this heat sink 108 and die-bonded using conductive adhesive 104. Terminal pads provided on a part of wiring patterns 102 and 103 and LED chip 105 are electrically coupled with wire 106, typically gold, by wire-bonding. This LED chip 105 and varistor element 135 are coupled in parallel in the circuitry.

Next, transparent resin 107 covers wire 106 and LED chip 105 to insulate and protect LED chip 105 and wire 106 and also act as a lens. This transparent resin 107 is preferably thermosetting acrylic resin or epoxy resin.

With the above structure, when noise such as static electricity is input to LED chip 105, varistor element 135 coupled in parallel absorbs the static electricity and thus protects LED chip 105 from electrostatic breakdown. Accordingly, a small surface-mount LED assembly with good antistatic characteristic is achievable. Here, it is important to set the heat conductivity of heat sink 108 higher than the heat conductivity of wiring substrate 101. Therefore, this heat sink 108 is preferably made of metal with good heat conductivity. Of metals with good heat conductivity, it is particularly preferable to use aluminum, copper, or silver. It is further preferable to use a ceramic substrate which has good heat resistance as wiring substrate 101 in addition to the use of metal with good heat conductivity for heat sink 108.

Still more, an LED assembly with further higher heat resistance and insulation performance is achievable by using ceramic substrates which have good heat resistance and insulation performances, typically alumina, forsterite, steatite, or low-temperature co-fired ceramic substrate, for heat sink 108. For applications which require further higher heat dissipation performance and heat resistance, ceramic materials with even better heat conductivity such as aluminum nitride, silicon carbide, or silicon nitride may be used.

In the structure shown in FIG. 15, a copper plate that enables heat dissipation is placed on a circuit board on which the LED assembly will be mounted, and the rear face of heat sink 108 is directly fixed onto this copper plate using adhesive with good heat conductivity. This can dissipate efficiently and directly the heat discharged from heat sink 108 to the copper plate disposed on the circuit board.

Still more, when the LED assembly is mounted, typically on a circuit board, the use of a metal for heat sink 108 establishes grounding to the circuit board via heat sink 108. The use of adhesive with good heat conductivity or solder for fixing heat sink 108 onto the circuit board also increases the mounting strength.

When insulation is needed between LED chip 105 and heat sink 108, a thin insulation coating can be formed on one face of heat sink 108 made of metal where LED chip 105 will be mounted. However, since the insulation coating hinders heat dissipation, the insulation coating is preferably made as thin as possible.

When wiring patterns 102 and 103 and LED chip 105 are coupled using wire 106, the reliability after wire-bonding can be improved by plating bonding pads of wiring patterns 102 and 103 with nickel or gold.

For soldering the LED assembly onto the circuit board, a plated nickel film or plated tin film is preferably laminated on a soldering portions of wiring patterns 102 and 103 to avoid any changes in the electrode material of wiring patterns 102 and 103 by inter-diffusion of the electrode materials.

Next, another structure of the LED assembly shown in FIG. 16 is described.

A difference in the LED assembly shown in FIG. 16 compared to that of the LED assembly shown in FIG. 15 is a cavity configured using the inner side face of opening 112 in wiring substrate 101. This cavity is formed by providing heat sink 108 which is thinner than that of wiring substrate 101 to lower the level of the placement area of LED chip 105 to below the surface level of wiring substrate 1. Another difference is that the inner periphery of opening 112 configuring this cavity is tapered as reflecting surface 109 when LED chip 105 emits light. Still another difference is that varistor element 135 is mounted on a face of wiring substrate 101 different from the face where LED chip 105 is mounted.

The LED assembly shown in FIG. 16 is provided with reflecting surface 109, compared to the LED assembly shown in FIG. 15. This structure realizes an LED assembly with better luminous efficiency. A taper on the inner periphery of this opening 112 is preferably processed to a shape that efficiently reflects light. More specifically, a conical or curved taper achieves an LED assembly with good reflectivity.

Still more, reflective coating 110, which is a thin film made of a metal with good reflectivity, is provided on the surface of the inner periphery of opening 112 where this reflecting surface 109 is created.

This reflective coating 110 may also be provided on the surface of heat sink 108 on which LED chip 105 is mounted. This achieves the LED assembly with even better reflectivity.

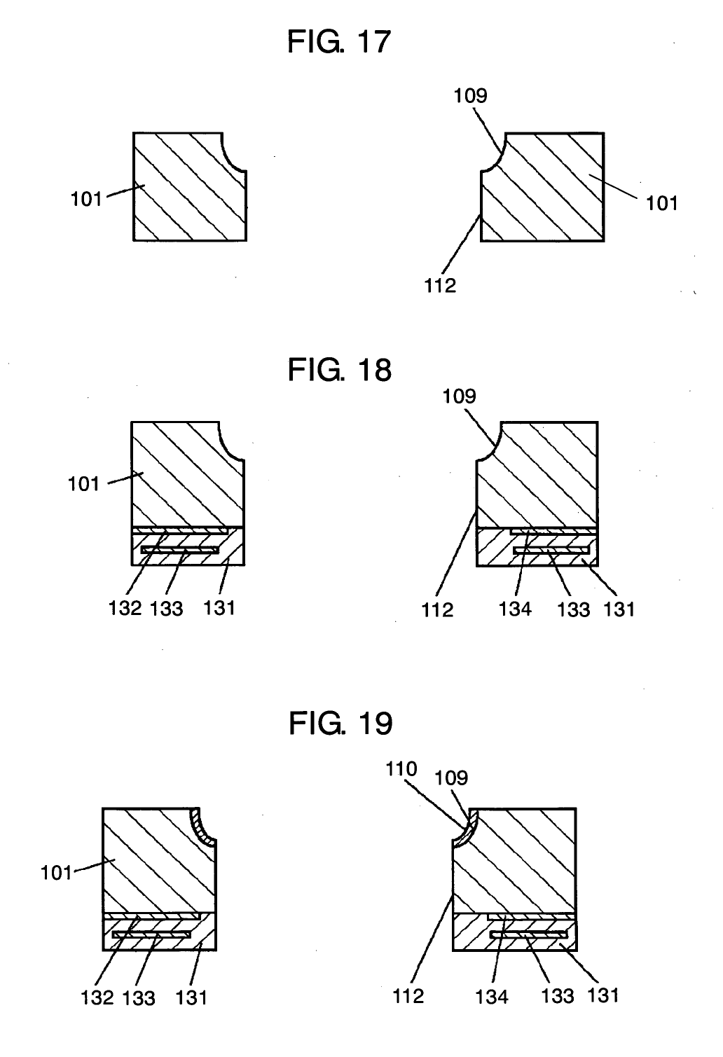

Next, a manufacturing method of the LED assembly shown in the fourth exemplary embodiment is described with reference to FIGS. 17 to 22. In the fourth exemplary embodiment, the method of manufacturing the LED assembly shown in FIG. 16 configured with heat sink 108 made of metal and wiring substrate 101 made of the alumina substrate is described.

In the first step, as shown in a sectional view in FIG. 17, reflecting surface 109 and opening 112 for inserting heat sink 108 are created to fabricate the alumina substrate into wiring substrate 101 (hereafter referred to as “alumina substrate 101” in some cases).

Next, as shown in FIG. 18, varistor electrodes 132 and 134 are screen-printed on the other face of alumina substrate 101, using silver paste. Then, varistor material 131 in the form of a ceramic green sheet of varistor composition is pressed and laminated onto the other face of alumina substrate 101 for tentative bonding in a way such that to cover varistor electrodes 132 and 134. Varistor electrode 133 is then screen-printed using silver paste, and the ceramic green sheet of varistor composition is press-bonded again. After removing binder from varistor electrodes 132, 133, and 134, and varistor material 131; they are fired at around 900° C. to complete varistor element 135.

Then, as shown in FIG. 19, reflective coating 110 is formed on alumina substrate 101 by applying silver (Ag) paste, which has high reflectivity, to reflecting surface 109 and heating it so that the light emitted from LED chip 105 is efficiently reflected. In particular, as for Ag paste, Ag resinated paste or Ag nano-paste is preferable for achieving smooth reflecting surface 109 after metallization. If copper paste is used for reflective coating 110, good reflective coating 110 is achievable by plating Ag on the copper surface.

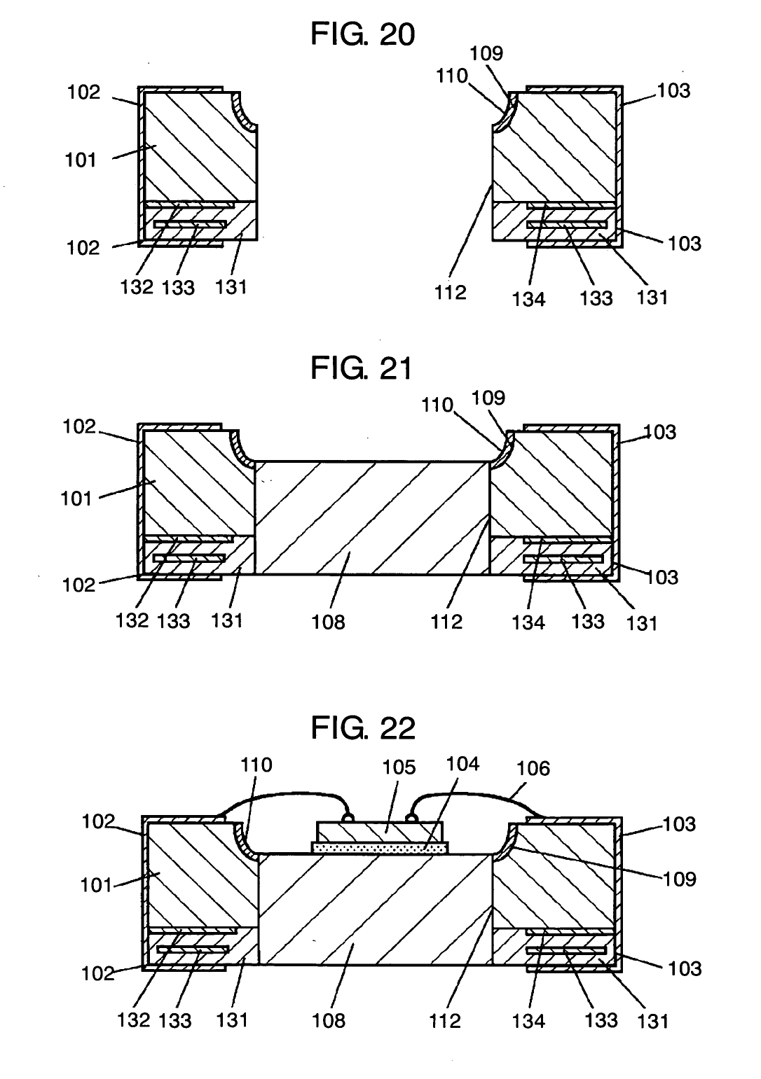

Next, as shown in FIG. 20, wiring patterns 102 and 103 which act as a connector and terminal electrode are metallized on alumina substrate 101 by printing conductive paste, typically Ag paste or gold (Au) paste. Ag paste includes Ag paste, Ag—Pt paste, and Ag—Pd paste. Au paste includes Au—Pd paste and Au—Pt paste.

In the second step, metal with good heat conductivity, typically aluminum or copper, is punched to a predetermined shape as heat sink 108.

Next, in the third step, as shown in FIG. 21, this heat sink 108 is press-fitted or fixed inside opening 112, using adhesive. As for adhesive, a conductive adhesive with good heat dissipation performance such as for thermal via and die-bonding is preferably used to suppress the drop in heat conductivity due to the adhesive. High-temperature firing adhesive which uses low-melting point glass as an inorganic binder is also applicable. In particular, bonding by brazing demonstrates high reliability in a thermal shock resistance test.

When copper is used for heat sink 108, the thermal shock resistance improves by the use of adhesive that allows chemical bond with alumina substrate 101 to build a spinnel structure in copper aluminate.

In the fourth step, as shown in FIG. 22, LED chip 105 is fixed onto one face of heat sink 108 using adhesive 104.

Then, in the fifth step, LED chip 105 and an electrode pad provided on wiring patterns 102 and 103 are electrically coupled with gold wire 106 by wire-bonding using a wire bonder. Here, LED chip 105 and varistor element 135 are coupled in parallel. This circuit configuration achieves an LED assembly with good antistatic characteristic.

Next, in the sixth step, transparent resin 107, which has good transparency, typically acrylic resin or epoxy resin, is coated. Transparent resin 107 insulates and protects LED chip 105 and also acts as a lens for converging the light emitted from LED chip 105. This completes the LED assembly shown in FIG. 16. Here, an appropriate viscosity or application method is selected to form transparent resin 107 with a predetermined lens shape. In addition, this transparent resin 107 may also act to reinforce bonding between wiring substrate 101 and heat sink 108.

As described above, heat sink 108 with good heat conductivity is disposed inside opening 112 created in a part of wiring substrate 101 where LED chip 105 will be placed. Varistor element 135 is also built in wiring substrate 101, and LED chip 105 and varistor element 135 are coupled in parallel. This structure can achieve a surface-mount LED assembly with good heat dissipation performance and antistatic characteristic, and its manufacturing method.

### Fifth Exemplary Embodiment

An LED assembly in the fifth exemplary embodiment of the present invention is described next with reference to drawings.

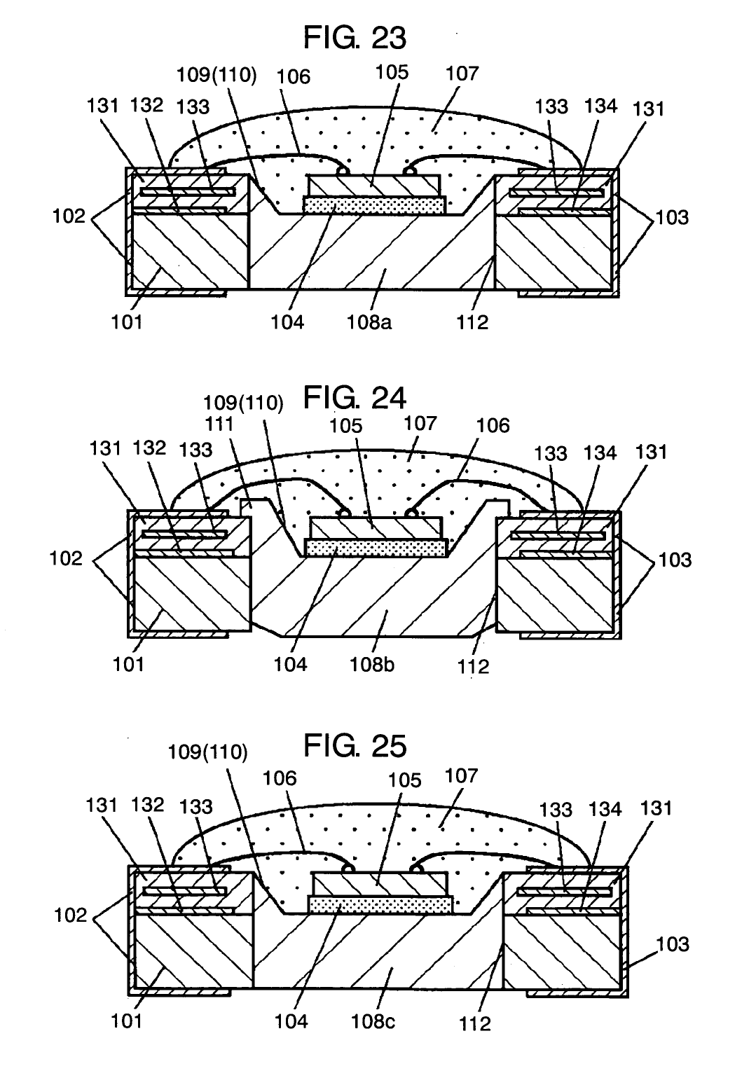

FIG. 23 is a sectional view illustrating a structure of a surface-mount LED assembly in the fifth exemplary embodiment of the present invention. FIG. 24 is a sectional view illustrating another example.

In FIGS. 23 and 24, a significant difference in the structure of the LED assembly in the fifth exemplary embodiment, compared to that of the fourth exemplary embodiment, is the shape of heat sinks 108a and 108b. In particular, heat sinks 108a and 108b are characterized by their cavity created by making a concave portion.

Heat sinks 108a and 108b made of metal with good heat conductivity, typically aluminum, copper or silver, can be easily molded to form the cavity. A space for mounting LED chip 105 is provided on the bottom of this cavity in heat sinks 108a and 108b.

The inner periphery of the concave portion which forms the cavity in these heat sinks 108a and 108b is tapered by molding, using dies, or polishing to form reflecting surface 109. This reflecting surface 109 is tapered at a predetermined angle for efficiently converging the light emitted from LED chip 105 placed on the bottom of the cavity, and increasing the luminous efficiency. Accordingly, light emission from the LED assembly is controllable.

This tapered reflecting surface 109 on the inner periphery of the concave portion can be processed to a mirrored surface to further improve light reflection.

In addition, reflective coating 110 of a material with a higher reflectivity may be applied to this reflecting surface 109 using thin-film technologies including plating and deposition on the surface so as to more efficiently reflect the light from LED chip 105.

Next, another example of the structure of the LED assembly shown in FIG. 24 is described. This LED assembly is characterized by claw 111 which is simultaneously molded by using a metal plate for heat sink 108b. Provision of this claw 111 regulates and retains the depth of insertion when heat sink 108b is inserted into opening 112 in wiring substrate 101.

This claw 111 may have continuous protrusions like a guard.

As described above, in the fifth exemplary embodiment, a cavity is easily created by machining heat sinks 108a and 108b made of metal where LED chip 105 will be placed. In addition, reflecting surface 109 may also be simultaneously formed. Accordingly, this structure achieves a shorter LED assembly of high productivity.

A ceramic material that has good heat conductivity may also be molded into the shape of heat sinks 108a and 108b. In this case, an LED assembly with good heat resistance is achievable in addition to the above effects.

### Sixth Exemplary Embodiment

An LED assembly and its manufacturing method in the sixth exemplary embodiment of the present invention are described next with reference to drawings.

FIG. 25 is a sectional view of the LED assembly in the sixth exemplary embodiment. The basic structure of a surface-mount LED assembly in the sixth exemplary embodiment is mostly the same as that of the LED assembly shown in FIG. 23. A significant difference, compared to that of with the fifth exemplary embodiment, is the material of heat sink 108c.

This heat sink 108c is made of resin containing metal filler which has good heat conductivity. This metal filler is metal powder of typically copper, aluminum, gold, or silver. Resin paste is made by kneading this metal powder with epoxy resin. This resin paste containing metal filler is filled in opening 112 created in wiring substrate 101, and then thermally cured. Thermal curing allows formation of heat sink 108c and bonding with wiring substrate 101 simultaneously. Accordingly, an LED assembly of high productivity is achievable.

Still more, if inorganic filler is used instead of this metal filler, the LED assembly with good insulation performance is achievable as well as the effect described above. The use of inorganic filler, typically aluminum oxide, aluminum nitride, silicon carbide, or magnesium oxide, achieves the LED assembly of high productivity. In other words, the resin paste, to which a heat-conducting filler of metal or ceramic powder with good heat conductivity is added, is filled in opening 112 in wiring substrate 101, and then this resin paste is thermally cured for fabricating heat sink 108c. Other points of the structure are mostly the same as that of the fifth exemplary embodiment, and thus their descriptions are omitted here.

This structure allows attachment of wiring substrate 101 and heat sink 108c at the same time as thermally curing the resin paste. In addition, expansion coefficients of wiring substrate 101 and heat sink 108c are controllable by changing the material composition of resin paste.

In the above description, metal filler or inorganic filler is mixed with epoxy resin and cured to form heat sink 108c. Alternately, high-temperature firing paste using an inorganic binder, such as glass frit, is also applicable instead of epoxy resin.

In the LED assembly in the sixth exemplary embodiment, as described above, heat sink 108c of high productivity can be formed on wiring substrate 101 on which LED chip 105 will be placed. Compared to processing of heat sinks 108a and 108b used in the fifth exemplary embodiment, heat sink 108c can be screen-printed inside opening 112. Accordingly, there is no need for preparing heat sinks 108a and 108b processed to individual dimensions. This can improve the productivity when there is many variations in the shape of opening 112.

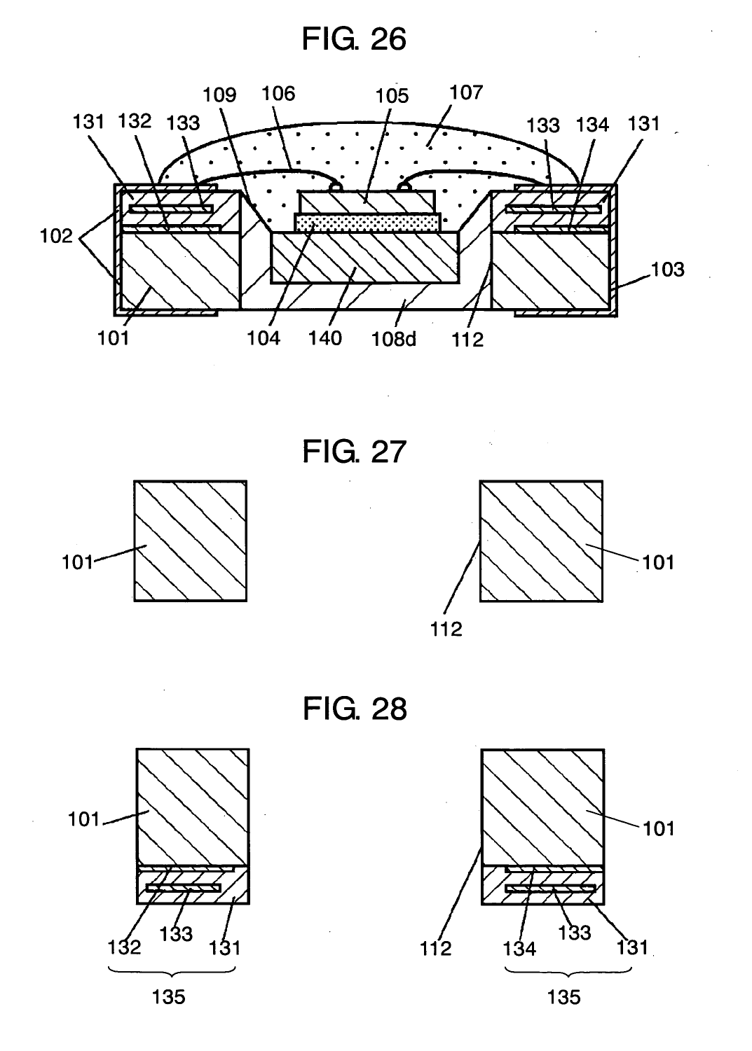

Next, another example of the structure of the LED assembly is described with reference to FIG. 26. This LED assembly, as shown in FIG. 26, has heat sink 140 made of metal or ceramic that has better flatness and heat conductivity on the bottom of a concave portion of heat sink 108d made of resin paste containing filler with good heat conductivity. This structure improves flatness of the surface where LED chip 105 will be mounted, giving an advantage in enlarging the size of LED chip 105.

For heat sink 140, metals with good heat conductivity, typically gold, silver, aluminum, or copper; or ceramics, typically alumina, aluminum nitride, silicon carbide, or magnesium oxide, can be used.

Next, a manufacturing method of the LED assembly shown in FIG. 25 is described with reference to FIGS. 27 to 32.

In the first step, as shown in FIG. 27, wiring substrate 101 in which opening 112 is created at a predetermined position is fabricated. Then, as shown in FIG. 28, varistor electrodes 132, 133, and 134, and varistor material 131 are laminated and fired to form varistor element 135 in the same way as that of the fourth exemplary embodiment.

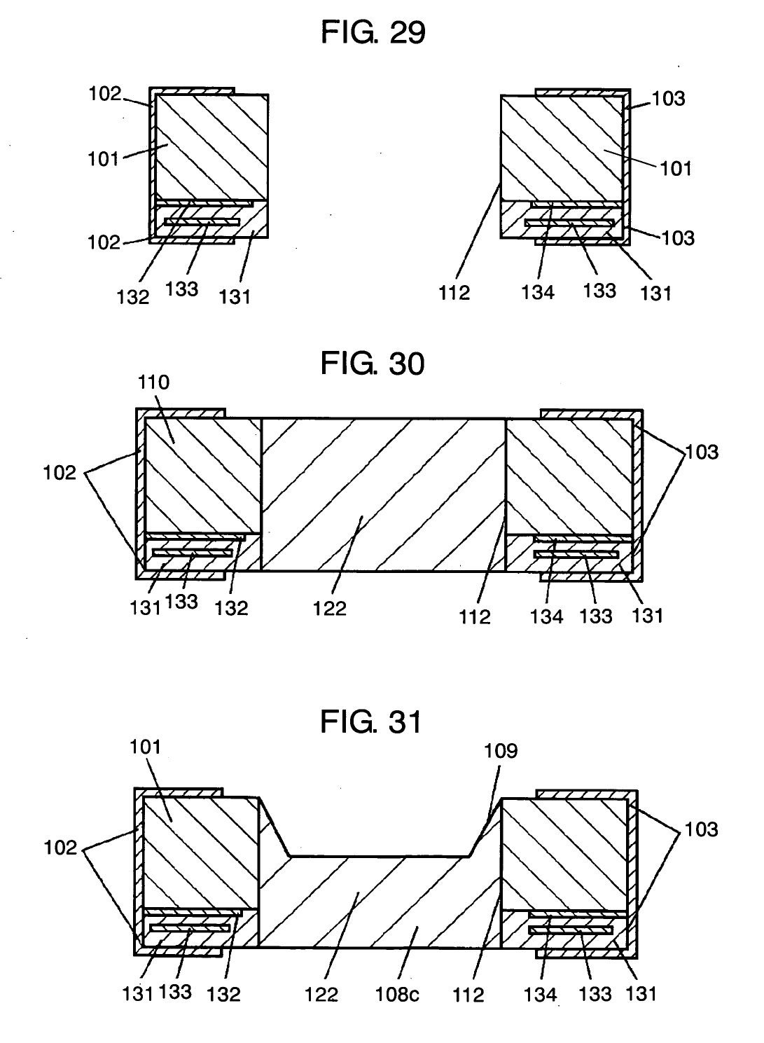

Next, as shown in FIG. 29, wiring patterns 102 and 103 are printed, and then fired together to fabricate wiring substrate 101 with built-in varistor element 135.

In the second step, as shown in FIG. 30, resin paste 122 containing metal filler with good heat conductivity, typically aluminum, copper, or silver, is filled in opening 112 by screen-printing.

In the third step, as shown in FIG. 31, filled resin paste 122 containing metal filler is heated and cured to form heat sink 108c. At the same time, heat sink 108c is attached to wiring substrate 101. The metal filler used here is preferably metal powder which has good heat conductivity, typically gold, silver, aluminum, or copper. An intended heat sink 108c can be designed by changing the content rate of this metal filler.

In the same way as metal filler, inorganic filler is also applicable. The use of ceramic power with good heat conductivity, typically aluminum oxide, aluminum nitride, silicon carbide, or magnesium oxide, as inorganic filler can achieve an LED assembly with good heat resistance and moisture resistance.

For resin paste 122, a material with less shrinkage at curing is preferably used. Thermally-cured resin paste 122 may also be machined to the shape of heat sink 108c shown in FIG. 31. The shape of heat sink 108c can be designed to have the same function as heat sink 108a described in the fifth exemplary embodiment.

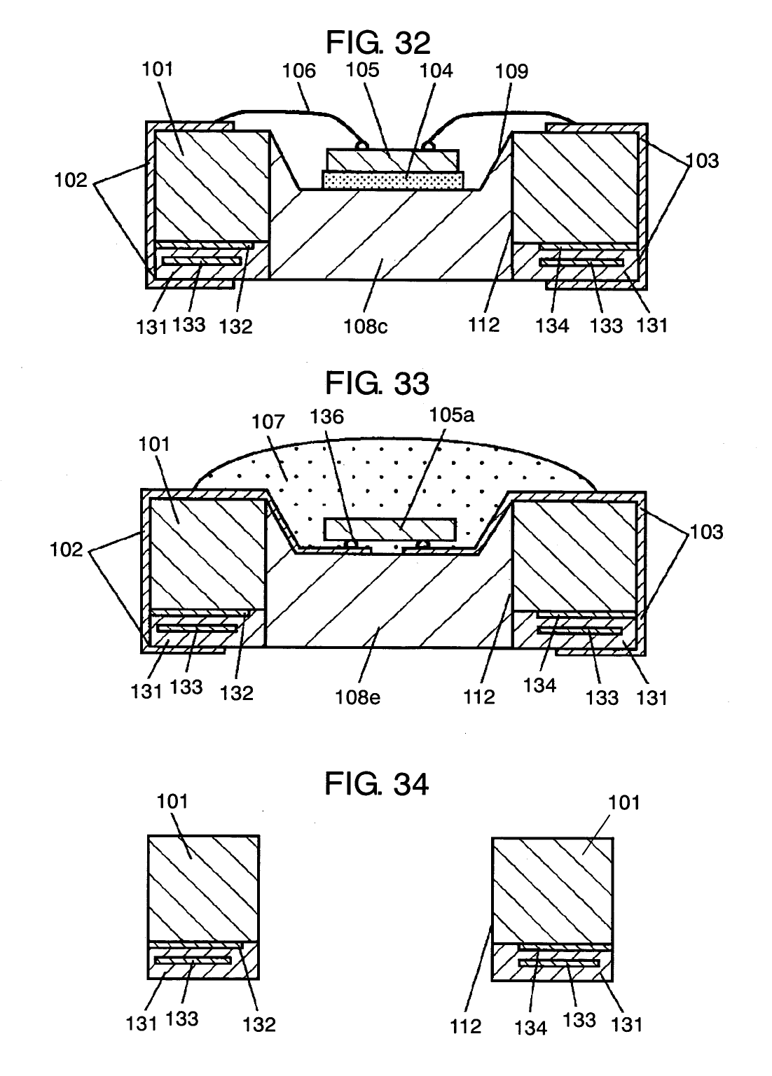

Then, in the fourth step, as shown in FIG. 32, LED chip 105 is fixed to the bottom of the concave portion of heat sink 108c using adhesive 104.

Next, in the fifth step, a pad provided on a part of wiring patterns 102 and 103 and LED chip 105 are electrically coupled with gold wire 106 by wire-bonding using a wire-bonder. Here, LED chip 105 and varistor element 135 are coupled in parallel.

Next, in the sixth step, transparent resin 107 with good transparency is coated to protect LED chip 105 and wire 106, and to act as a lens for converging emitted light. This completes the surface-mount LED assembly.

As described above, in the sixth exemplary embodiment, heat sink 108c can be formed at high productivity on wiring substrate 101 where LED chip 105 will be placed. Accordingly, a shorter surface-mount LED assembly with good antistatic characteristic and its manufacturing method are achievable.

### Seventh Exemplary Embodiment

An LED assembly and its manufacturing method in the seventh exemplary embodiment are described next with reference to drawings.

FIG. 33 is a sectional view of the LED assembly in the seventh exemplary embodiment, and FIGS. 34 to 38 are sectional views illustrating its manufacturing method.

As shown in FIG. 33, the basic structure of a surface-mount LED assembly in the seventh exemplary embodiment is mostly the same as the structure of the LED assembly shown in FIG. 25. A significant difference, compared to the LED assembly shown in FIG. 25, is the use of face-down bonding of a flip chip instead of wire-bonding for mounting LED chip 105. Accordingly, in the LED assembly in the seventh exemplary embodiment, heat sink 108e and wiring patterns 102 and 103 need to be electrically insulated. Therefore, a thin insulation coating is preferably formed on the surface of heat sink 108e when heat sink 108e is, for example, made of metal. LED chip 105a of a flip-chip type is mounted on a pad of wiring patterns 102 and 103 formed on heat sink 108e. Heat sink 108e with good insulation performance can be achieved by making this heat sink 108e with insulation material mainly containing inorganic filler with good heat conductivity and glass frits with low melting point as an additive. Inorganic filler is preferably a fired insulation paste made with typically aluminum oxide, aluminum nitride, silicon carbide, or magnesium oxide as inorganic binder; silicide glass with low melting point, typically of boron glass, bismuth glass or zinc glass; and organic vehicle. The use of such insulation paste enables efficient injection of the resin paste to various shapes of opening 112, achieving an LED assembly of high productivity. Wiring patterns 102 and 103 are formed on this heat sink 108e with good insulation performance so that LED chip 105a of a flip-chip type can be bump-bonded.

The above structure achieves a shorter LED assembly which can improve productivity by an efficient mounting process.

Next, a manufacturing method of the LED assembly in the seventh exemplary embodiment is described with reference to FIGS. 34 to 38.

In the first step, as shown in FIG. 34, opening 112 is created at a predetermined position in wiring substrate 101. Varistor electrodes 132, 133, and 134, and varistor material 131 are laminated on the other face of wiring substrate 101, same as in the sixth exemplary embodiment, to fabricate wiring substrate 101 with built-in varistor element 135.

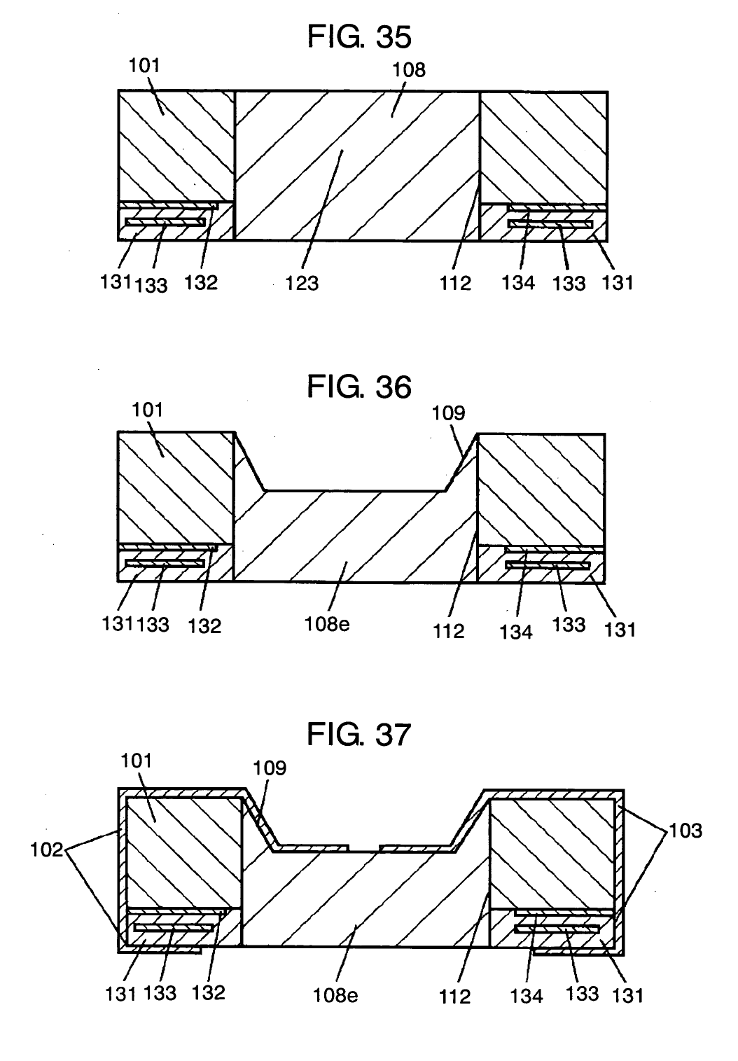

In the second step, as shown in FIG. 35, insulation paste 123 mainly containing inorganic filler with good heat conductivity, typically aluminum nitride or silicon carbide, is filled in opening 112 by screen-printing. The use of ceramic powder with good heat conductivity, typically aluminum oxide, aluminum nitride, silicon carbide, or magnesium oxide, as inorganic filler in resin paste 123 achieves the LED assembly with high durability including good heat resistance and moisture resistance.

In the third step, filled resin paste 123 is cured or fired to complete heat sink 108. At the same time, heat sink 108 and wiring substrate 101 are bonded. For resin paste 123, a material with less shrinkage by curing or firing is preferably used.

Next, cured or fired resin paste 123 is machined to the shape of heat sink 108e, as shown in FIG. 36, as required. The same function as heat sink 108c described in the sixth exemplary embodiment is achievable depending on the shape of heat sink 108e.

Then, in the fourth step, as shown in FIG. 37, wiring patterns 102 and 103 are formed using conductive paste by screen-printing or thin-film technology.

Here, wiring patterns 102 and 103 are formed on wiring substrate 101 and heat sink 108e. On heat sink 108e, wiring patterns 102 and 103 are patterned to the shape of pad electrode to which LED chip 105a for flip-chip can be bump-bonded.

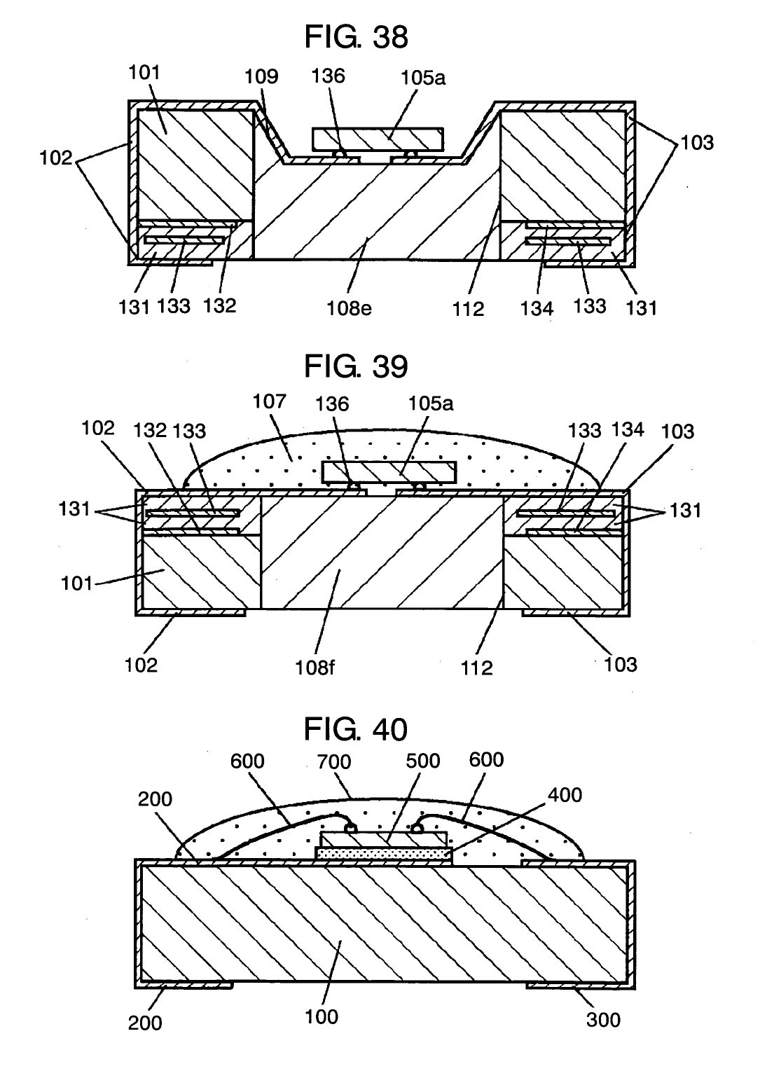

In the fifth step, as shown in FIG. 38, LED chip 105a is bump-mounted and fixed onto the bottom of a concave portion of heat sink 108e using gold bump 136 formed on LED chip 105a.

In this way, LED chip 105a and the bump pad provided on a part of wiring patterns 102 and 103 of wiring substrate 101 are electrically coupled by bump-bonding using gold bump 136. Here, LED chip 105a and varistor element 135 are coupled in parallel.

In the sixth step, transparent resin 107 with good transparency is coated to protect LED chip 105a and also act as a lens for converging emitted light. Coated transparent resin 107 covers the entire LED chip 105a and a portion of wiring patterns 102 and 103 which couples LED chip 105a and wiring substrate 101.

Through the steps described above, the surface-mount LED assembly shown in FIG. 33 is completed.

The LED assembly shown in FIG. 39 is a sectional view of another example of the LED assembly in the seventh exemplary embodiment. This LED assembly is characterized by no concave portion on heat sink 108f. The LED assembly shown in FIG. 39 is effective for irradiating light from LED chip 105a at a wider angle.

As described above, the seventh exemplary embodiment achieves a smaller and shorter LED assembly by flip-chip mounting of LED chip 105a and providing heat sinks 108e and 108f of high productivity on wiring substrate 101.

### INDUSTRIAL APPLICABILITY

The present invention offers the LED assembly which can efficiently dissipate the heat generated when the LED chip emits light. This is achieved by providing the heat sink with good heat conductivity, where the LED chip is placed, inside the opening in the wiring substrate. Furthermore, a built-in varistor is effective for a high-luminous LED assembly and its manufacturing method. This can use efficiently the mounting area of the LED chip, and also reduce defects of the LED chip 105 due to surge or static electricity.

1. An LED assembly comprising:
a wiring substrate in which an opening is created;
a heat sink housed inside the opening;
an LED chip mounted on the heat sink;
a connecting section for electrically coupling the LED chip and the wiring substrate; and
a transparent resin covering the LED chip and the connecting section.

2. The LED assembly of claim 1, wherein the connecting section is a metal wire.

3. The LED assembly of claim 1, wherein the heat sink is thinner than the wiring substrate, and the LED chip is disposed on a concave portion formed by the heat sink and the wiring substrate.

4. The LED assembly of claim 3, wherein an inner periphery of the opening is tapered.

5. The LED assembly of claim 4 further comprising a reflective coating on a tapered surface of the inner periphery.

6. The LED assembly of claim 1, wherein a concave portion is created in a part of the heat sink, and a wall face of an inner periphery of the concave portion is tapered.

7. The LED assembly of claim 6 further comprising a reflective coating on the wall face of the inner periphery of the heat sink.

8. The LED assembly of claim 1 further comprising a conductive adhesive for bonding the heat sink and the wiring substrate.

9. The LED assembly of claim 1, wherein heat conductivity of the heat sink is higher than heat conductivity of the wiring substrate.

10. The LED assembly of claim 1, wherein the heat sink is metal.

11. The LED assembly of claim 1, wherein the heat sink is ceramic.

12. The LED assembly of claim 1, wherein the heat sink is a resin containing metal filler.

13. The LED assembly of claim 12, wherein the metal filler is at least one of copper, aluminum, silver, and gold.

14. The LED assembly of claim 1, wherein the heat sink is a resin containing inorganic filler.

15. The LED assembly of claim 14, wherein the inorganic filler is at least one of aluminium oxide, aluminium nitride, silicon carbide, and magnesium oxide.

16. The LED assembly of claim 1, wherein the wiring substrate is a wiring substrate with a built-in varistor element, and the LED chip and the varistor element are coupled in parallel.

17. The LED assembly of claim 16, wherein the varistor element is made of a material containing ZnO, Bi₂O₃, and Sb₂O₃, a content rate of ZnO being at least 80 wt %.

18. The LED assembly of claim 16, wherein the LED chip and the wiring substrate with the built-in varistor element are coupled by flip-chip bonding.

19. A manufacturing method of an LED assembly comprising:
a first step of fabricating a wiring pattern and an opening at a wiring substrate;
a second step of fabricating a heat sink which can be disposed inside the opening;
a third step of attaching the wiring substrate and the heat sink inside the opening by one of press-fitting and adhesive;
a fourth step of bonding an LED chip on one face of the heat sink using an adhesive for die-bonding;
a fifth step of coupling the LED chip and the wiring substrate; and
a sixth step of covering the LED chip with a transparent resin.

20. The manufacturing method of an LED assembly of claim 19, wherein the fifth step is a step of coupling the LED chip and the wiring substrate using a wire, and the LED chip and the wire are covered with the transparent resin in the sixth step.

21. The manufacturing method of an LED assembly of claim 19, wherein a tapered reflecting surface is formed on an inner periphery of the opening in the first step.

22. The manufacturing method of an LED assembly of claim 21, wherein a thin shiny reflective coating is formed on the reflecting surface of the inner periphery of the opening in the first step.

23. The manufacturing method of an LED assembly of claim 19, wherein a concave portion is formed on one face of the heat sink, and a tapered reflecting surface is formed on an inner periphery of the concave portion in the second step.

24. The manufacturing method of an LED assembly of claim 23, wherein a thin shiny reflective coating is formed on the reflecting surface of the heat sink in the second step.

25. The manufacturing method of an LED assembly of claim 19, wherein the first step includes a step of forming a varistor element at the wiring substrate, and the LED chip and the varistor element are coupled in parallel in the fifth step.

26. A manufacturing method of an LED assembly comprising:
a first step of forming a wiring pattern and an opening at a wiring substrate;
a second step of forming a heat sink inside the opening in the wiring substrate by filling a resin paste containing heat-conductive filler;
a third step of bonding the wiring substrate and the heat sink by thermally curing the filled resin paste;
a fourth step of bonding an LED chip on one face of the heat sink using an adhesive for die-bonding;
a fifth step of coupling the LED chip and the wiring substrate; and
a sixth step of covering the LED chip using a transparent resin.

27. The manufacturing method of an LED assembly of claim 26, wherein the fifth step is a step of coupling the LED chip and the wiring substrate using a wire; and the LED chip and the wire are covered with the transparent resin in the sixth step.

28. The manufacturing method of an LED assembly of claim 26, wherein an inner periphery of the opening is tapered in the first step.

29. The manufacturing method of an LED assembly of claim 28, wherein a thin shiny reflective coating is formed on a surface of the tapered inner periphery of the opening in the first step.

30. The manufacturing method of an LED assembly of claim 26, wherein a concave portion is formed on one face of the heat sink, and an inner periphery of the concave portion is tapered in the second step.

31. The manufacturing method of an LED assembly of claim 30, wherein a thin shiny reflective coating is formed on a surface of the inner periphery of the tapered concave portion of the heat sink in the second step.

32. The manufacturing method of an LED assembly of claim 26, wherein the first step includes a step of forming a varistor element at the wiring substrate, and the LED chip and the varistor element are coupled in parallel in the fifth step.

33. A manufacturing method of an LED assembly comprising:
a first step of forming a varistor element and an opening at a wiring substrate;
a second step of filling an insulation paste inside the opening, the insulation paste mainly containing heat-conductive filler and inorganic binder, the inorganic binder being a glass with a low melting point;
a third step of forming a heat sink by firing the filled insulation paste, and bonding the heat sink and the wiring substrate;
a fourth step of forming a wiring pattern having an electrode pad for mounting an LED chip on one face of the heat sink;
a fifth step of coupling the LED chip and the varistor element in parallel by bump-bonding the LED chip on the electrode pad; and
a sixth step of covering the LED chip with a transparent resin.

34. The manufacturing method of an LED assembly of claim 33, wherein a tapered reflecting surface is formed on an inner periphery of the opening in the first step.

35. The manufacturing method of an LED assembly of claim 34, wherein a reflective coating is further formed on the reflecting surface in the first step.

36. The manufacturing method of an LED assembly of claim 33, wherein a concave portion is formed on one face of the heat sink, and a tapered reflecting surface is formed on an inner periphery of the concave portion in the second step.

37. The manufacturing method of an LED assembly of claim 36, wherein a reflective coating is further formed on the reflecting surface in the second step.
